(19) United States
(12) Patent Application Publication
(10) Pub. No.: US 2025/0251238 A1
(43) Pub. Date: Aug. 7, 2025

(54) SEMICONDUCTOR PACKAGE AND MODULE

(71) Applicant: SONY SEMICONDUCTOR SOLUTIONS CORPORATION, Kanagawa (JP)

(72) Inventor: Yasuhiro OCHIAI, Kanagawa (JP)

(73) Assignee: SONY SEMICONDUCTOR SOLUTIONS CORPORATION, Kanagawa (JP)

(21) Appl. No.: 18/710,284

(22) PCT Filed: Sep. 30, 2022
(86) PCT No.: PCT/JP2022/036689

§ 371 Date: May 15, 2024

(30) Foreign Application Priority Data
Nov. 25, 2021 (JP) 2021-190665

(51) Int. Cl. G01B 21/30; G01P 1/00; G01P 15/02

(52) U.S. Cl. CPC G01B 21/30; G01P 1/00; G01P 15/02

(57) ABSTRACT

To improve the measurement accuracy of a sensor in a semiconductor package provided with the sensor. A semiconductor package includes a laminated chip and a measurement unit. In the semiconductor package including the laminated chip and the measurement unit, the laminated chip measures a temperature and estimates a degree of warpage of the laminated chip on the basis of the temperature. Moreover, in the semiconductor package, the measurement unit performs processing of measuring a predetermined physical quantity and generating measurement information and processing of correcting the measurement information on the basis of the degree of warpage.

### TECHNICAL FIELD

The present technology relates to a semiconductor package. Specifically, the present technology relates to a semiconductor package and a module in which a plurality of chips are laminated and mounted.

### BACKGROUND ART

Conventionally, for the purpose of saving the area, semiconductor packages on which a plurality of chips and substrates are laminated and mounted have been used. For example, a semiconductor package in which a first substrate, a circuit substrate, and an opening substrate provided with an opening are laminated and a sub-chip is attached in a space formed by the opening and the circuit substrate has been proposed (e.g., see Patent Literature 1). The sub-chip is provided with a gyroscope and the like.

### CITATION LIST

### Patent Literature

Patent Literature 1: WO 2019/021705

### DISCLOSURE OF INVENTION

### Technical Problem

In the above-mentioned conventional technology, the use of the opening substrate facilitates mounting of the sub-chip. However, in some cases, the first substrate or the circuit substrate generates heat during the operation of the circuit and warpage is caused in such a substrate. In a case where the sub-chip is provided with a sensor such as a gyroscope, warpage of the substrate may lower the measurement accuracy of the sensor.

The present technology has been made in view of such circumstances and it is an object of the present technology to improve the measurement accuracy of a sensor in a semiconductor package provided with the sensor.

### Solution to Problem

The present technology has been made in order to overcome the above-mentioned problem, and a first aspect thereof is a semiconductor package including: a laminated chip that measures a temperature and estimates a degree of warpage of the laminated chip on the basis of the temperature; and a measurement unit that performs processing of measuring a predetermined physical quantity and generating measurement information and processing of correcting the measurement information on the basis of the degree of warpage. Accordingly, the measurement accuracy of the sensor in the measurement unit is improved as an effect.

Moreover, in this first aspect, the measurement unit may correct the measurement information on the basis of the temperature and the degree of warpage. Accordingly, the measurement accuracy is further improved as an effect.

Moreover, in this first aspect, the semiconductor package may further include a substrate having a cavity formed in a predetermined substrate flat surface, in which a chip flat surface of the laminated chip may be connected to a predetermined region of the substrate flat surface, which surrounds the cavity, and the measurement unit may be disposed in a region of the chip flat surface, which is exposed in the cavity. Accordingly, the sensor having the movable portion can be mounted as an effect.

Moreover, in this first aspect, in the predetermined region of the substrate flat surface, which surrounds the cavity, a ground pattern and a terminal disposed in vicinity of the ground pattern may be disposed. Accordingly, the laminated chip and the substrate are electrically connected to each other as an effect.

Moreover, in this first aspect, in the predetermined region of the substrate flat surface, which surrounds the cavity, a ground pattern including an island-like region and a terminal formed inside the island-like region may be disposed. Accordingly, a resistance value of the ground pattern is reduced as an effect.

Moreover, in this first aspect, the semiconductor package may further include a dummy silicon disposed in the region of the chip flat surface, which is exposed in the cavity. Accordingly, warpage of the laminated chip and distributed heat concentration are reduced as an effect.

Moreover, in this first aspect, the laminated chip may include a plurality of chips laminated, and any one of the plurality of chips and the substrate may be joined to each other through a wire. Accordingly, the laminated chip and the substrate are electrically connected to each other as an effect.

Moreover, in this first aspect, the laminated chip and the substrate may be connected to each other with a resin. Accordingly, the laminated chip and the substrate can be easily connected to each other as an effect.

Moreover, in this first aspect, the semiconductor package may further include a metal plate bonded to the substrate. Accordingly, warpage of the substrate is reduced as an effect.

Moreover, in this first aspect, the measurement unit may include an inertial sensor that has a movable portion exposed in the cavity and generates inertial information as the measurement information, and a correction circuit that corrects the inertial information on the basis of the degree of warpage. Accordingly, the measurement accuracy of the inertial sensor is improved as an effect.

Moreover, in this first aspect, the measurement unit may further include a silicon cap that seals the movable portion. Since the inside of the silicon cap is kept in a vacuum state, it becomes unnecessary to put the inside of the cavity in a vacuum state as an effect.

Moreover, in this first aspect, the laminated chip may include a sensor chip that generates image data. Accordingly, the image data can be captured as an effect.

Moreover, in this first aspect, the sensor chip may process the image data by using the corrected measurement information. Accordingly, the image quality of the image data is improved as an effect.

Moreover, a second aspect of the present technology is a module including: a laminated chip that measures a temperature and estimates a degree of warpage of the laminated chip on the basis of the temperature; and a measurement unit that performs processing of measuring a predetermined physical quantity and generating measurement information and processing of correcting the measurement information on the basis of the degree of warpage. Accordingly, the measurement accuracy of the sensor in the measurement unit provided in the module is improved as an effect.

### BRIEF DESCRIPTION OF DRAWINGS

FIG. 1 A cross-sectional view showing a configuration example of a semiconductor package in a first embodiment of the present technology.

FIG. 2 An example of a top view of the semiconductor package in the first embodiment of the present technology.

FIG. 3 An example of a top view of a substrate in the first embodiment of the present technology.

FIG. 4 A block diagram showing a configuration example of the semiconductor package in the first embodiment of the present technology.

FIG. 5 An example of a cross-sectional view of the semiconductor package in the first embodiment of the present technology, where a plurality of inertial measurement units is provided.

FIG. 6 An example of a cross-sectional view of the semiconductor package in the first embodiment of the present technology, where MEMS are reduced.

FIG. 7 A diagram showing an example of a temperature distribution on an upper surface of a semiconductor package in a comparative example.

FIG. 8 A diagram showing an example of a magnitude of oscillation on the upper surface of the semiconductor package in the comparative example.

FIG. 9 A cross-sectional view showing a configuration example of a sensor module in the first embodiment of the present technology.

FIG. 10 An example of a top view of a substrate in a modified example of the first embodiment of the present technology.

FIG. 11 A cross-sectional view showing a configuration example of a semiconductor package in a second embodiment of the present technology.

FIG. 12 A cross-sectional view showing a configuration example of a semiconductor package in a third embodiment of the present technology.

FIG. 13 A cross-sectional view showing a configuration example of a semiconductor package in a fourth embodiment of the present technology.

FIG. 14 A cross-sectional view showing a configuration example of the semiconductor package in the fourth embodiment of the present technology when a connection target for a wire has been changed.

FIG. 15 A cross-sectional view showing a configuration example of a semiconductor package in a modified example of the fourth embodiment of the present technology.

FIG. 16 A cross-sectional view showing a configuration example of a semiconductor package in a fifth embodiment of the present technology.

FIG. 17 A block diagram depicting an example of schematic configuration of a vehicle control system.

FIG. 18 A diagram of assistance in explaining an example of installation positions of an imaging section.

### MODE(S) FOR CARRYING OUT THE INVENTION

Hereinafter, mode(s) for carrying out the present technology (hereinafter, referred to as embodiment(s)) will be described. The descriptions will be given in the following order.
1. First Embodiment (Example of Drift-Correcting Inertial Information)
2. Second Embodiment (Example of Sealing Movable Portion with Silicon Cap and Drift-Correcting Inertial Information)
3. Third Embodiment (Example of Disposing Dummy Silicon and Drift-Correcting Inertial Information)
4. Fourth Embodiment (Example of Joining with Wires and Drift-Correcting Inertial Information)
5. Fifth Embodiment (Example of Bonding Metal Plate to Substrate and Drift-Correcting Inertial Information)
6. Application Examples to Movable Objects

### 1. First Embodiment

### [Configuration Example of Semiconductor Package]

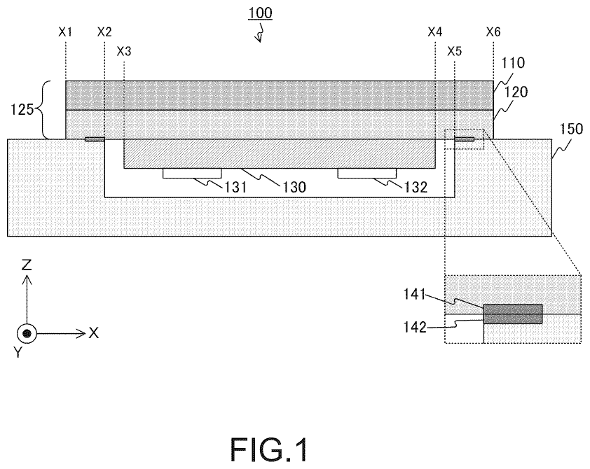

FIG. 1 is a cross-sectional view showing a configuration example of a semiconductor package 100 in a first embodiment of the present technology. The semiconductor package 100 is a package mounted on an imaging apparatus or the like and includes a laminated chip 125, an inertial measurement unit (IMU) 130, and a substrate 150. The laminated chip 125 includes a sensor chip 110 and a control chip 120 which are laminated on each other. It should be noted that although the semiconductor package 100 further includes a frame and a glass for protecting the laminated chip 125, these are both omitted from the figure.

Hereinafter, a predetermined axis parallel to a substrate flat surface of the substrate 150 is defined as an “X-axis” and a predetermined axis perpendicular to the substrate flat surface is defined as a “Z-axis.” An axis perpendicular to the X-axis and the Z-axis is defined as a “Y-axis.” The figure is a cross-sectional view when viewed in the Y-axis direction.

The sensor chip 110 generates image data by photoelectric conversion. For example, a complementary MOS (CMOS) image sensor is used as the sensor chip 110. Moreover, the sensor chip 110 measures a temperature and generates temperature information indicating the measurement value. The temperature information is supplied to the control chip 120 and the inertial measurement unit 130.

The sensor chip 110 is laminated on one chip flat surface of both surfaces of the control chip 120 and the inertial measurement unit 130 is disposed on the other chip flat surface. Hereinafter, a direction from the inertial measurement unit 130 to the sensor chip 110 is defined as an “upper” direction. Moreover, the sensor chip 110 and the control chip 120 are electrically connected to each other and the control chip 120 and the inertial measurement unit 130 are also electrically connected to each other. For electrically connecting the control chip 120 and the sensor chip 110 (or the inertial measurement unit 130) to each other, a through silicon via (TSV) or Cu—Cu connection is used.

Here, the sensor chip 110 or the control chip 120 may generate heat during an operation. When it generates heat, the laminated chip 125 may be warped due to different coefficients of thermal expansion between the sensor chip 110 and the control chip 120. The control chip 120 estimates a degree of warpage of the laminated chip 125 on the basis of the temperature information from the sensor chip 110 and generates warpage information indicating the result. The warpage information is supplied to the inertial measurement unit 130.

It should be noted that the sensor chip 110 measures the temperature, though not limited to this configuration. The control chip 120 may measure the temperature in place of the sensor chip 110. Moreover, although the control chip 120 estimates the degree of warpage, the sensor chip 110 may estimate the degree of warpage in place of the control chip 120.

It is assumed that the area of the sensor chip 110 in an X-Y plane is substantially the same as the control chip 120. Moreover, it is assumed that the area of the substrate 150 in the X-Y plane is larger than the control chip 120. A laminated substrate obtained by alternately laminating a conductor layer and an insulating layer or the like is used as the substrate 150. It should be noted that the substrate 150 is not limited to the laminated substrate, and may be a printed board, a silicon board, or the like.

Moreover, a cavity is formed in an upper substrate flat surface of the substrate 150. The area of the cavity in the X-Y plane is smaller than the control chip 120 and a lower chip flat surface of the control chip 120 is connected to a region of the substrate flat surface, which surrounds the cavity. Therefore, a part of the lower chip flat surface of the control chip 120 is exposed in the cavity.

In the figure, X1 and X6 denote coordinates of both ends of the control chip 120 in the X-axis direction. Moreover, X2 and X5 denote coordinates of both ends of the cavity in the X-axis direction. In this case, a region of from X1 to X2 and a region of from X5 to X6 of the substrate flat surface are electrically connected to the control chip 120 with terminals 141 and 142 of an electric conductor. The terminal 141 is formed in the control chip 120 and the terminal 142 is formed in the substrate 150. These terminals are joined to each other inside a vacuum apparatus. During the joining, the terminals may be joined together by adding metal such as solder or silver solder to each terminal and fusing it by heat or the terminals may be joined together with an alloy by chemical reaction. It should be noted that although a ground pattern is further formed in the substrate flat surface, it is omitted from the figure.

The inertial measurement unit 130 measures a predetermined physical quantity (e.g., acceleration and angular velocity) in an inertial system. The inertial measurement unit 130 is disposed in a region of the lower chip flat surface of the control chip 120, which is exposed in the cavity. X3 and X4 denote coordinates of both ends of the inertial measurement unit 130 in the X-axis direction. It should be noted that the inertial measurement unit is an example of a measurement unit described in the scope of claims.

Moreover, the inertial measurement unit 130 is provided with a predetermined number of micro electro mechanical systems (MEMS). These MEMS function as inertial sensors that measure the physical quantity (e.g., acceleration) in the inertial system. Moreover, the MEMS have movable portions and the movable portions are exposed in the cavity. For example, two MEMS are provided in the inertial measurement unit 130 and their movable portions 131 and 132 are exposed in the cavity. By joining the terminals 141 and 142 to each other inside the vacuum apparatus as described above, the cavity in which the movable portions 131 and 132 are exposed can be put in a vacuum state. Accordingly, it is possible to reduce influences due to distributed load and air resistance and the oscillation efficiency during resonance of the MEMS can be increased. For example, the Q factor during resonance of the MEMS increases.

As described above, the laminated chip 125 may be warped due to a change in temperature. In this case, the MEMS are provided in the inertial measurement unit 130 attached to the laminated chip 125, and therefore inertial information generated by the MEMS may have an error. Moreover, when heat generated by the sensor chip 110 and the control chip 120 is transferred to the inertial measurement unit 130 and changes the temperature of the inertial measurement unit 130, inertial information may have an error due to the change in temperature. The dynamic error of the inertial information due to the warpage and the change in temperature is called drift. The inertial measurement unit 130 corrects the drift of the inertial information on the basis of the warpage information and the temperature information from the control chip 120. Accordingly, the accuracy of the inertial information can be improved.

The corrected inertial information is used in various types of image processing (e.g., shake correction) for image data generated by the sensor chip 110.

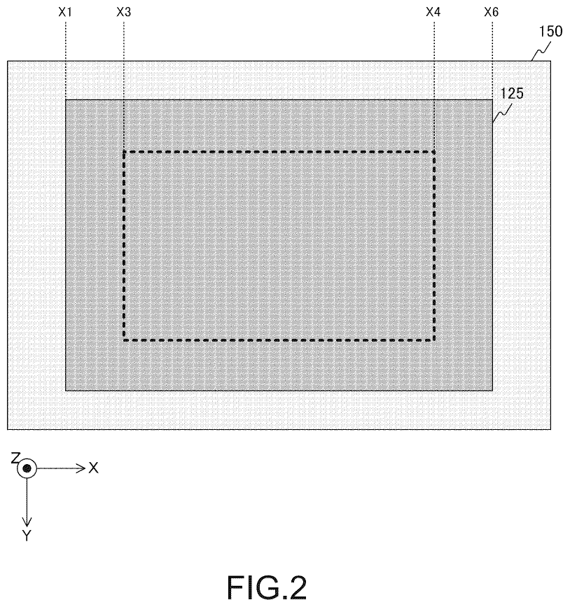

FIG. 2 is an example of a top view of the semiconductor package 100 in the first embodiment of the present technology. The area of the substrate 150 in the X-Y plane is larger than the laminated chip 125. Moreover, the inertial measurement unit 130 (not shown) smaller in area is laminated on the lower chip flat surface of the laminated chip 125. The thick dotted line in the figure indicates an outer periphery of the inertial measurement unit 130.

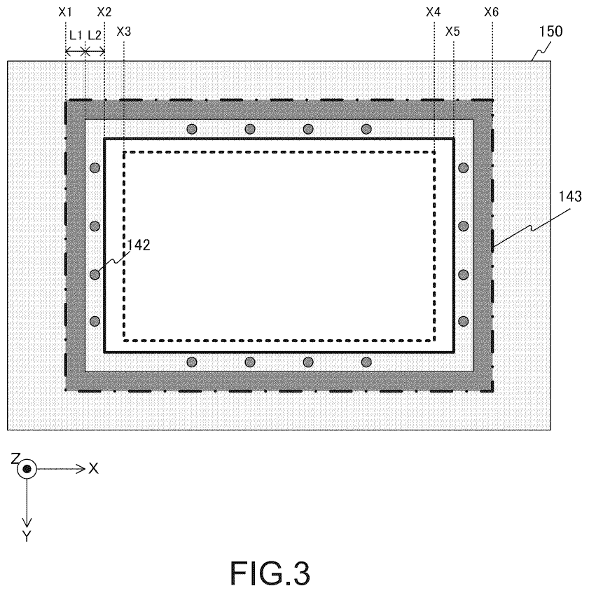

FIG. 3 is an example of a top view of the substrate 150 in the first embodiment of the present technology. A cavity is formed in an upper substrate flat surface of the substrate 150. The rectangular thick solid line in the figure indicates an outer periphery of the cavity. The inertial measurement unit 130 (not shown) is disposed in the cavity. The thick dotted line in the figure indicates an outer periphery of the inertial measurement unit 130.

Moreover, the area of the control chip 120 (not shown) connected to the substrate 150 is larger than the cavity. The thick long dashed short dashed line in the figure indicates an outer periphery of the control chip 120. In the surrounding region of the cavity, a ground pattern 143 is formed and a plurality of terminals 142 is formed in vicinity of it. The ground pattern 143 in a ring shape with a width of L1 is formed for example along the outer periphery of the control chip 120. In a ring shaped region with a width of L2 inside the ground pattern 143, the plurality of terminals 142 is formed. Signals and power are supplied via these terminals 142. Moreover, a constant clearance is provided between the ground pattern 143 and the terminal 142 in order to avoid a short-circuit.

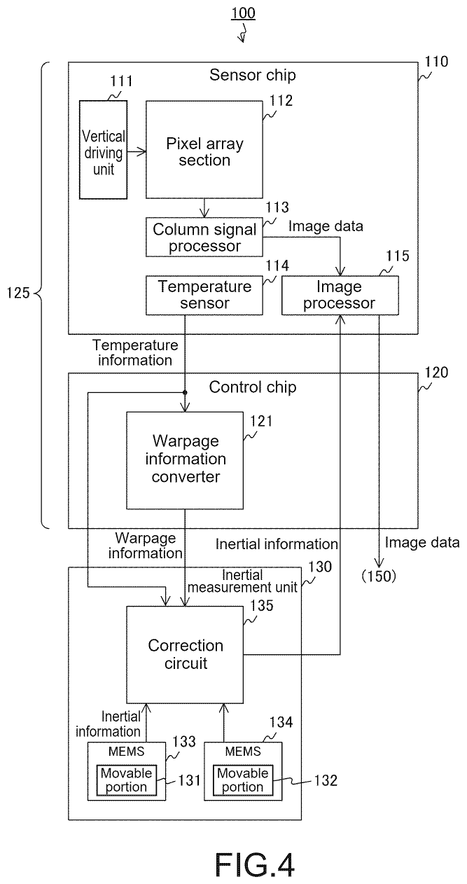

FIG. 4 is a block diagram showing a configuration example of the semiconductor package 100 in the first embodiment of the present technology. The semiconductor package 100 includes the sensor chip 110, the control chip 120, the inertial measurement unit 130, and the substrate 150.

The sensor chip 110 includes a vertical driving unit 111, a pixel array section 112, a column signal processor 113, a temperature sensor 114 and an image processor 115. In the pixel array section 112, a plurality of pixels (not shown) is arranged in a two-dimensional grid form. Each of the pixels generates a pixel signal by photoelectric conversion and supplies the pixel signal to the column signal processor 113.

The vertical driving unit 111 sequentially drives rows and causes them to output pixel signals. The column signal processor 113 performs various types of signal processing with respect to the pixel signals for each column. As the signal processing, analog to digital (AD) conversion processing or correlated double sampling (CDS) processing is executed. The column signal processor 113 supplies image data in which the processed pixel signals are arranged to the image processor 115. The image processor 115 may be located in the sensor chip 110 or may be located in the control chip 120.

The temperature sensor 114 measures a temperature at a predetermined position on the sensor chip 110. The temperature sensor 114 measures the temperature regularly or at a predetermined timing, for example, while a predetermined circuit in the sensor chip 110 is operating. The temperature sensor 114 generates temperature information indicating the measurement value and supplies the temperature information to the control chip 120 and the inertial measurement unit 130.

It should be noted that the temperature sensor 114 is provided in the sensor chip 110, though not limited to this configuration. The temperature sensor 114 may be arranged in the control chip 120, not in the sensor chip 110.

The image processor 115 performs predetermined image processing on image data from the column signal processor 113. The processed image data is supplied to the substrate 150. Moreover, when receiving inertial information from the inertial measurement unit 130, the image processor 115 is capable of performing image processing such as shake correction by using the inertial information. This shake correction improves the image quality of the image data. By sensor fusion combining the CMOS image sensor (sensor chip 110) with the inertial measurement unit 130 as described above, a sensor with a high added value can be realized.

It should be noted that the processing using the inertial information is not limited to the shake correction. For example, a serviceman can wear an apparatus on which the semiconductor package 100 is mounted and perform processing of recognizing and analyzing the serviceman's behaviors by using image data and inertial information from the apparatus for improving the work. Details of the processing are described in for example “https://www.researchgate.net/figure/Illustration-of-the-feature-transforms-for-wearable-sensor-signals_fig3_335319090.” Alternatively, serviceman's movement speed and position information may be acquired from the inertial information and processing of three-dimensionally modeling a site where the serviceman is located by using them and image data may be performed. Details of the processing are described in for example “https:/unit.aist.go.jp/hiri/cfsr/2011/symposium0317/kurata20110328.pdf.”

Moreover, the sensor chip 110 performs the processing using the inertial information, though not limited to this configuration. A circuit inside the control chip 120 or the substrate 150 may perform the processing using the inertial information. Alternatively, a circuit outside the semiconductor package 100 may perform the processing.

The control chip 120 includes a warpage information converter 121. The warpage information converter 121 converts temperature information into warpage information. The warpage information converter 121 supplies the acquired warpage information to the inertial measurement unit 130.

For example, the designer determines how much warpage occurs for each temperature by simulation and actual measurement, generates a table describing warpage information for each temperature, and stores the table in a memory (not shown) inside the control chip 120 or the like. Then, the warpage information converter 121 acquires the warpage information by reading the warpage information corresponding to the temperature from the table. Alternatively, the warpage information converter 121 converts the temperature information into the warpage information by performing arithmetic operation by using a predetermined function representing the relationship between the temperature and the warpage.

It should be noted that the warpage information converter 121 is disposed in the control chip 120, though not limited to this configuration. The warpage information converter 121 may be disposed in the sensor chip 110.

The inertial measurement unit 130 includes MEMS 133 and 134 and a correction circuit 135. The MEMS 133 have a movable portion 131 and generate inertial information. The MEMS 134 have a movable portion 132 and generate inertial information. The MEMS 133 and 134 supply the inertial information to the correction circuit 135. It should be noted that the MEMS 133 and 134 are examples of an inertial sensor described in the scope of claims.

The correction circuit 135 receives inertial information from the MEMS 133 and 134 and corrects (in other words, drift-corrects) the inertial information on the basis of the warpage information from the control chip 120 and the temperature information from the sensor chip 110. The correction circuit 135 supplies the corrected inertial information to the image processor 115. It should be noted that the MEMS 133 and 134 may have the same functions or may have different functions, for example, one of the MEMS 133 and 134 may measure acceleration and the other may measure angular velocity.

Moreover, the correction circuit 135 corrects the inertial information by using both the temperature information and the warpage information, though not limited to this configuration. The inertial information may be corrected by using only the warpage information or only the temperature information.

As described above, the laminated chip 125 measures a temperature and estimates a degree of warpage of the laminated chip on the basis of the temperature. Moreover, the inertial measurement unit 130 generates inertial information and corrects the inertial information on the basis of the estimated degree of warpage and the temperature. Accordingly, the measurement accuracy of the inertial measurement unit 130 can be improved.

It should be noted that the two MEMS are disposed in the inertial measurement unit 130, though the number of MEMS is not limited to two. One MEMS or three or more MEMS may be provided.

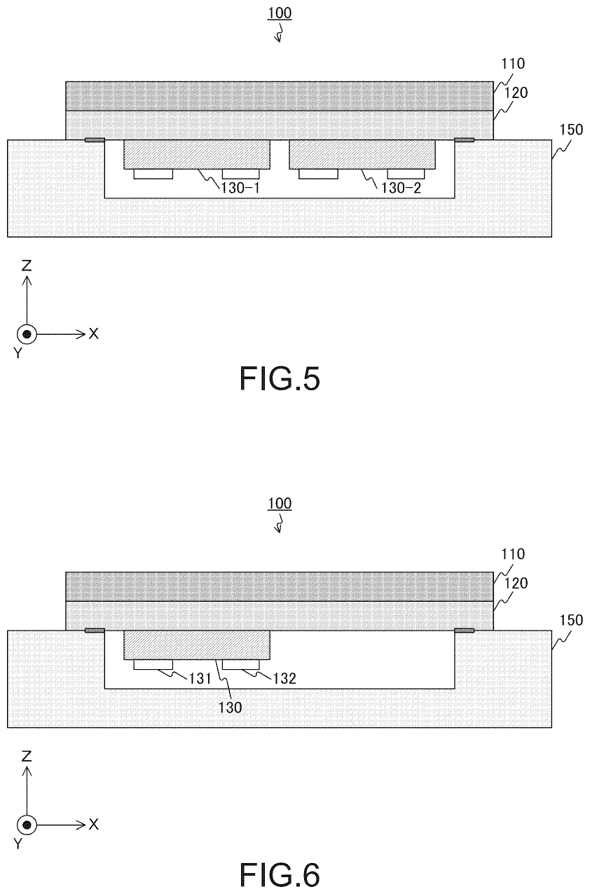

Moreover, as illustrated in FIG. 5, two or more inertial measurement units, e.g., inertial measurement units 130-1 and 130-2, may be provided in the semiconductor package 100.

Moreover, as illustrated in FIG. 6, in a case where a single inertial measurement unit 130 is provided, its position is not limited to the center portion of the chip flat surface of the control chip 120, and may be a position far from the center portion. In this case, for example, it is desirable to dispose the inertial measurement unit 130 at any one of the following positions.
(1) A position just below a circuit block where the power consumption of the control chip 120 or the sensor chip 110 concentrates.
(2) A position just below the temperature sensor disposed in the control chip 120 or the sensor chip 110.
(3) A position simultaneously satisfying (1) and (2).

By disposing the inertial measurement unit 130 at such a position, the temperature sensor 114 is capable of transmitting accurate temperature information about where heat is generated to the inertial measurement unit 130.

Here, a semiconductor package with a structure in which the laminated chip 125 and the inertial measurement unit 130 are not laminated is assumed as a comparative example.

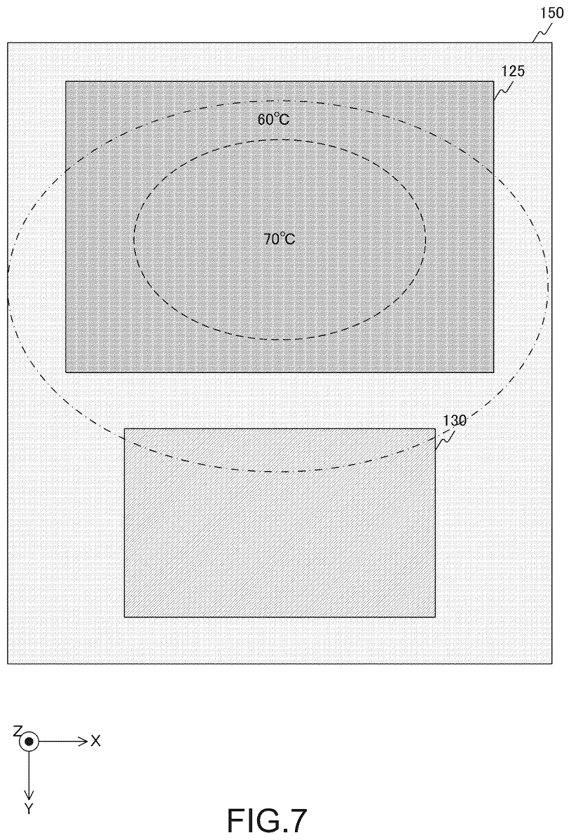

FIG. 7 is a diagram showing an example of a temperature distribution on the upper surface of the semiconductor package in the comparative example. As illustrated in the figure, in the comparative example, the laminated chip 125 and the inertial measurement unit 130 are not laminated and the inertial measurement unit 130 is disposed in vicinity of the laminated chip 125 in the substrate flat surface of the substrate 150.

It is assumed that the temperature at the center portion on the laminated chip 125 has increased to 70° C. and the temperature of the inertial measurement unit 130 in vicinity of it has increased to 60° C. by thermal conduction from the laminated chip 125. In this case, the temperature sensor mounted on the laminated chip 125 measures 70° C. and supplies it to the inertial measurement unit 130 and the inertial measurement unit 130 corrects the inertial information on the basis of the temperature.

As described above, in the comparative example, there is a difference between the measurement value (e.g., 70° C.) of the temperature sensor and the actual temperature (e.g., 60° C.) of the inertial measurement unit 130 and the inertial measurement unit 130 may be incapable of sufficiently correcting drift due to a change in temperature.

In this regard, as illustrated in FIGS. 1 and 2, in the configuration in which the laminated chip 125 and the inertial measurement unit 130 are laminated, the measurement value of the temperature sensor and the temperature of the inertial measurement unit 130 are substantially the same. Therefore, the inertial measurement unit 130 can improve the correction accuracy of the drift-correction.

Moreover, in the configuration in which the laminated chip 125 and the inertial measurement unit 130 are laminated as illustrated in FIG. 2, the area of the semiconductor package 100 can be made smaller than that of the comparative example illustrated in FIG. 7 in the X-Y plane.

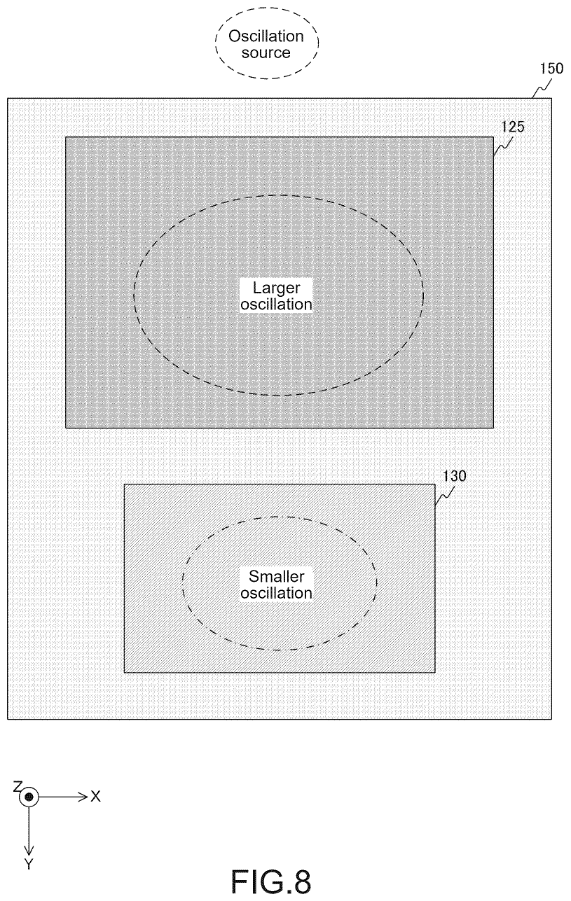

FIG. 8 is a diagram showing an example of a magnitude of oscillation on the upper surface of the semiconductor package in the comparative example. It is assumed that oscillation is caused in an oscillation source in vicinity of the substrate flat surface and the laminated chip 125 is closer to the oscillation source than the inertial measurement unit 130 in the substrate flat surface. In this case, the amount of oscillation in the laminated chip 125 at a shorter distance is larger than that in the inertial measurement unit 130. Therefore, in the shake correction based on the inertial information measured by the inertial measurement unit 130, the amount of correction is insufficient and the correction accuracy of the shake correction lowers.

In this regard, in the configuration in which the laminated chip 125 and the inertial measurement unit 130 are laminated as illustrated in FIG. 2, the amount of oscillation of the laminated chip 125 and the amount of oscillation of the inertial measurement unit 130 are substantially the same, and therefore the correction accuracy of the shake correction can be improved.

### [Configuration Example of Sensor Module]

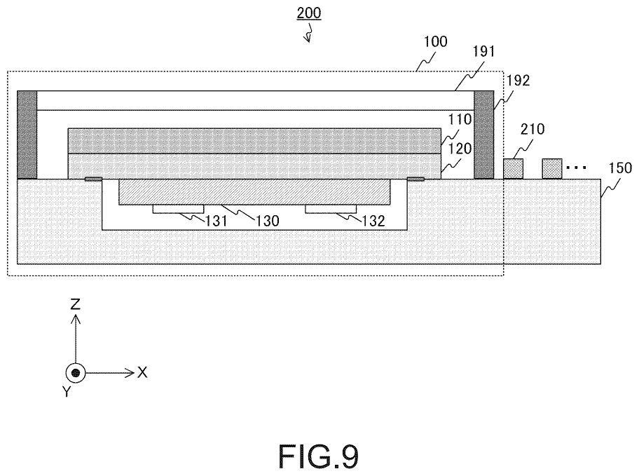

FIG. 9 is a cross-sectional view showing a configuration example of a sensor module 200 in the first embodiment of the present technology. The sensor module 200 includes the semiconductor package 100 with the structure illustrated in FIG. 1 and a predetermined number of electronic components 210. It should be noted that the sensor module 200 is an example of a module described in the scope of claims.

The semiconductor package 100 further includes, in addition to the sensor chip 110 and the like illustrated in FIG. 1, a frame 192 surrounding the sensor chip 110 and the control chip 120 and a glass 191 that protects an upper portion of the sensor chip 110.

The electronic components 210 are mounted in vicinity of the semiconductor package 100. For example, a capacitor, a resistor, and a regulator are used as the electronic components 210.

As described above, in accordance with the first embodiment of the present technology, the inertial measurement unit 130 corrects the inertial information on the basis of the degree of warpage estimated on the basis of the temperature and the temperature, and therefore the measurement accuracy of the MEMS 133 and 134 (in other words, inertial sensors) can be improved.

### Modified Example

In the above-mentioned first embodiment, the terminal 142 is disposed in vicinity of the ground pattern 143. In this configuration, it is difficult to further reduce a resistance value of the ground pattern 143. A semiconductor package 100 in a modified example of the first embodiment is different from that of the first embodiment in that the width of the ground pattern 143 is increased.

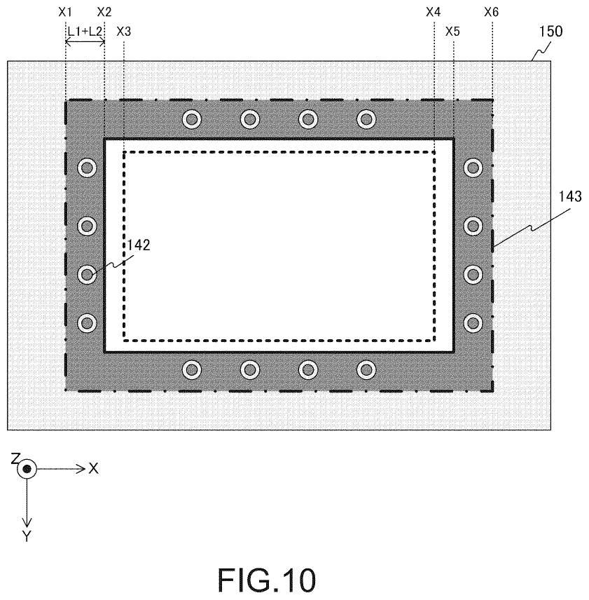

FIG. 10 is an example of a top view of the substrate 150 in the modified example of the first embodiment of the present technology. In the modified example of the first embodiment, the ground pattern 143 is formed in the entire surface of the region between the outer periphery (long dashed short dashed line) of the control chip 120 and the outer periphery (thick solid line) of the cavity. The width of the ground pattern 143 is L1+L2 and is larger than that of the first embodiment. Increasing the width of the ground pattern 143 can reduce its resistance value.

Moreover, a plurality of island-like regions is provided in the ground pattern 143 and the terminal 142 is formed in each region. In this case, a constant clearance is provided between the periphery of the terminal 142 and the outer periphery of the island-like region in order to avoid a short-circuit. The ring shaped grey portion in the periphery of the terminal 142 in the figure represents the clearance.

In both the first embodiment illustrated in FIG. 3 and the modified example illustrated in FIG. 10, it is necessary to connect the chip and the substrate to each other with no gaps in the portion where the terminal 142 and the ground pattern 143 are provided. It is because the portion of the inertial measurement unit 130 cannot retain the vacuum if there is a gap here.

As described above, in accordance with the modified example of the first embodiment of the present technology, the ground pattern 143 is made thicker, and therefore its resistance value can be reduced.

### 2. Second Embodiment

Although in the above-mentioned first embodiment, the inside of the cavity is vacuumed and the movable portions 131 and 132 are sealed, they may be sealed with a silicon cap. A semiconductor package 100 in the second embodiment is different from that of the first embodiment in that the movable portion 131 and the like are sealed by the use of the silicon cap.

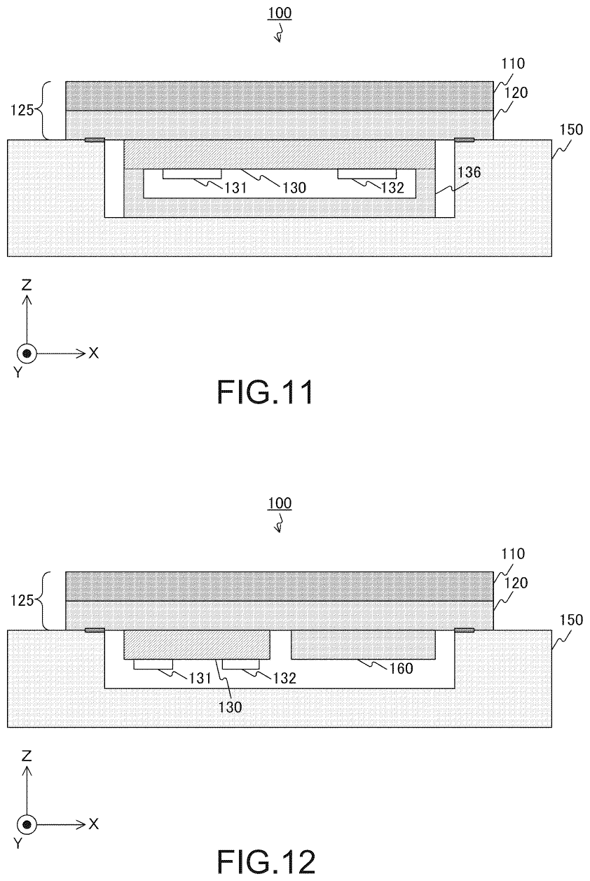

FIG. 11 is a cross-sectional view showing a configuration example of the semiconductor package 100 in the second embodiment of the present technology. The semiconductor package 100 in the second embodiment is different from the first embodiment in that it further includes a silicon cap 136.

The silicon cap 136 seals the movable portions 131 and 132. The inside of the silicon cap 136 is held in a vacuum state. Therefore, it becomes unnecessary to keep the inside of the cavity in a vacuum state. A manufacturing method for the silicon cap 136 has been described in for example Japanese Patent Application Laid-open No. 2008-288384.

It should be noted that the modified example of the first embodiment can be applied to the second embodiment.

As described above, in accordance with the second embodiment of the present technology, the silicon cap 136 seals the movable portions 131 and 132, and therefore it becomes unnecessary to put the inside of the cavity in a vacuum state.

### 3. Third Embodiment

In the above-mentioned first embodiment, only the inertial measurement unit 130 is disposed in the cavity. However, in a case where the inertial measurement unit 130 is not disposed at the center portion as illustrated in FIG. 6, it may be impossible to sufficiently reduce warpage of the control chip 120 and heat concentration at the inertial measurement unit 130. A semiconductor package 100 in a third embodiment is different from that in the first embodiment in that a dummy silicon is further disposed for the purpose of reducing warpage and heat concentration.

FIG. 12 is a cross-sectional view showing a configuration example of the semiconductor package 100 in the third embodiment of the present technology. The semiconductor package 100 in the third embodiment is different from that in the first embodiment in that a dummy silicon 160 is further disposed.

The dummy silicon 160 is a member made of silicon in which any circuit and element are not provided. The dummy silicon 160 is disposed in a region of the lower chip flat surface of the control chip 120, which is exposed in the cavity.

The installation of the dummy silicon 160 makes it possible to improve the balance of stress associated with the laminated chip 125 and reduce warpage of the laminated chip 125 even in a case where the inertial measurement unit 130 is not disposed at the center portion. Moreover, due to heat conduction inside the dummy silicon 160, a heat distribution on the laminated chip 125 can be dispersed and heat concentration at the inertial measurement unit 130 can be reduced.

It should be noted that the modified example of the first embodiment and the second embodiment can be applied to the third embodiment.

As described above, in accordance with the third embodiment of the present technology, the dummy silicon 160 is further disposed, and therefore warpage of the laminated chip 125 and heat concentration at the inertial measurement unit 130 can be reduced.

### 4. Fourth Embodiment

Although in the above-mentioned first embodiment, the sensor chip 110 and the substrate 150 are not connected to each other, they may be electrically connected to each other. A semiconductor package 100 in the fourth embodiment is different from that in the first embodiment in that the sensor chip 110 and the substrate 150 are joined to each other through wires.

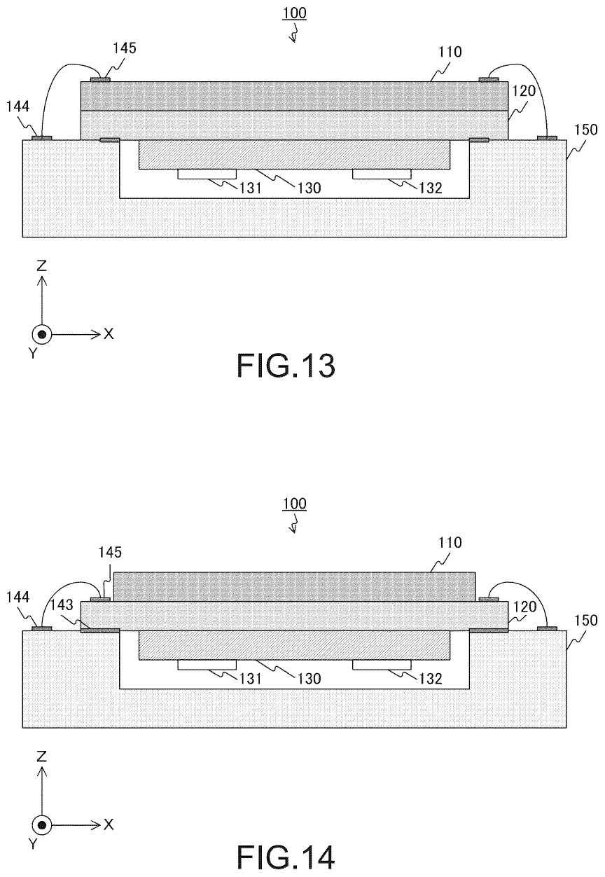

FIG. 13 is a cross-sectional view showing a configuration example of the semiconductor package 100 in the fourth embodiment of the present technology. In the semiconductor package 100 in the fourth embodiment, a predetermined number of pads 144 are formed on the substrate 150 and a predetermined number of pads 145 are formed on the sensor chip 110. These pads 144 and 145 are joined to each other through wires. The sensor chip 110 and the substrate 150 are electrically connected to each other by this wire bonding.

It should be noted that as illustrated in FIG. 14, the control chip 120 may be joined to the substrate 150 through wires in place of the sensor chip 110. In this case, it is necessary to secure a space for the pads 145 by making the area of the sensor chip 110 smaller than the control chip 120. Moreover, in a case where the control chip 120 is joined through a wire, the ground pattern 143 can be formed in the entire surface between the outer periphery of the control chip 120 and the outer periphery of the cavity as illustrated in FIG. 10. It should be noted that although the terminals 142 are disposed in the ground pattern 143 in FIG. 10, a configuration in which no terminals 142 are disposed may be possible in a case where the control chip 120 is joined with a wire.

Moreover, the second embodiment and the third embodiment can be applied to the fourth embodiment.

As described above, in accordance with the fourth embodiment of the present technology, the sensor chip 110 and the substrate 150 are joined with the wires, and therefore they can be electrically connected to each other.

### Modified Examples

Although in the fourth embodiment, the control chip 120 and the substrate 150 are connected through the terminals 141 and 142, it is necessary to perform thermal press fitting or the like in order to join the terminals to each other and thermal energy and mechanical energy become necessary. A semiconductor package 100 in a modified example of the fourth embodiment is different from that in the fourth embodiment in that the control chip 120 and the substrate 150 are connected to each other with a resin.

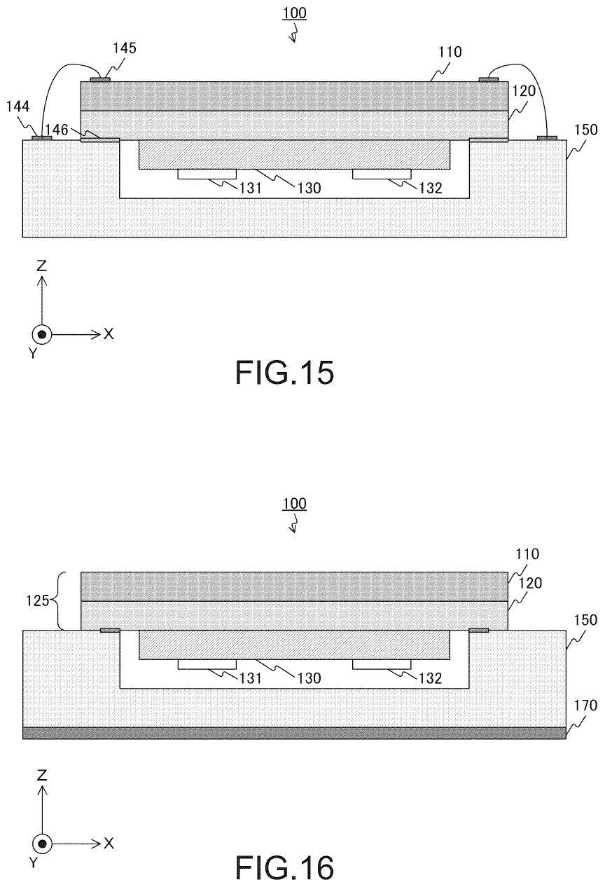

FIG. 15 is a cross-sectional view showing a configuration example of the semiconductor package 100 in the modified example of the fourth embodiment of the present technology. The modified example of the fourth embodiment is different from the fourth embodiment in that the control chip 120 and the substrate 150 are connected to each other with a resin 146 that functions as an adhesive. The connection with the resin 146 makes it unnecessary to perform thermal press fitting or the like, and thermal energy and mechanical energy required for the connection can be reduced.

It should be noted that the second embodiment and the third embodiment can be applied to the modified example of the fourth embodiment.

As describe above, in accordance with the modified example of the fourth embodiment of the present technology, the control chip 120 and the substrate 150 are connected to each other with the resin 146, and therefore the energy required for the connection can be reduced.

### 5. Fifth Embodiment

Although in the above-mentioned first embodiment, the control chip 120 is connected to the substrate 150, heat generated by the sensor chip 110 and the control chip 120 may also be transferred to the substrate and the substrate 150 may be warped due to different coefficients of thermal expansion. A semiconductor package 100 in fifth embodiment is different from that in the first embodiment in that a metal plate is bonded to the substrate 150.

FIG. 16 is a cross-sectional view showing a configuration example of the semiconductor package 100 in the fifth embodiment of the present technology. The semiconductor package 100 in the fifth embodiment is different from that in the first embodiment in that it further includes a metal plate 170.

The metal plate 170 is bonded to a lower surface of the substrate 150. A plate with high-hardness such as a steel plate of steel use stainless (SUS) is used as the metal plate. Warpage of the substrate 150 due to a change in temperature can be reduced by bonding of the metal plate 170.

It should be noted that the modified example of the first to fourth embodiments and the modified example of the fourth embodiment can be applied to the fifth embodiment.

As described above, in accordance with the fifth embodiment of the present technology, the metal plate 170 is bonded to the substrate 150, and therefore warpage of the substrate 150 can be reduced.

### 6. Application Examples to Movable Objects

The technology according to the present disclosure (present technology) can be applied to various products. For example, the technology according to the present disclosure may be realized as an apparatus mounted on any type of movable object such as an automobile, an electric automobile, a hybrid electric automobile, a motorcycle, a bicycle, a personal transporter, an airplane, a drone, a watercraft, or a robot.

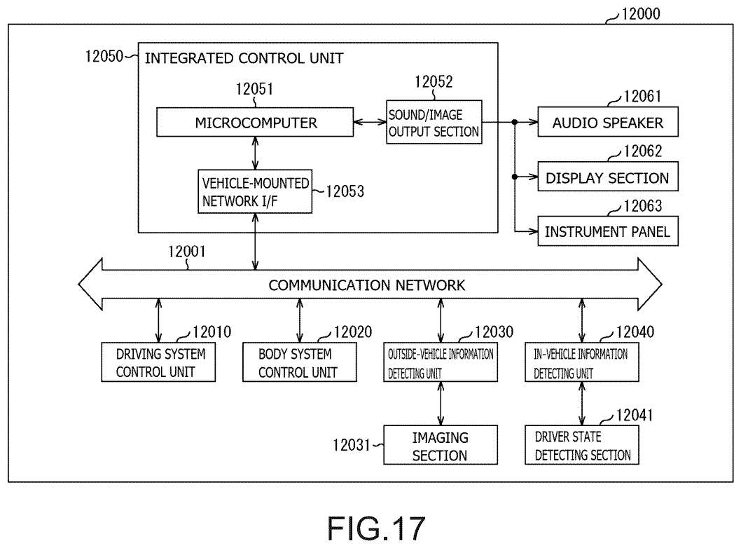

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

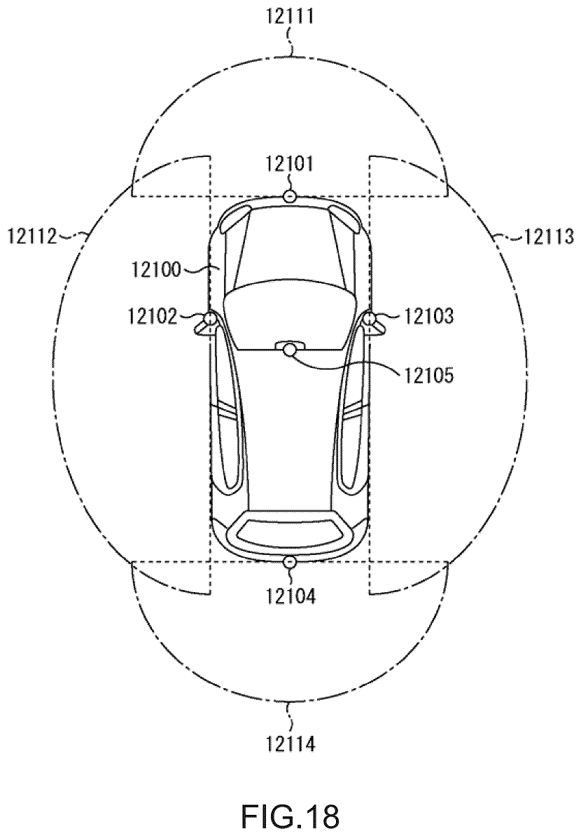

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Hereinabove, the example of the vehicle control system to which the technology according to the present disclosure can be applied has been described. The technology according to the present disclosure can be applied to the imaging section 12031 of the above-mentioned configurations. Specifically, the semiconductor package 100 in FIG. 1 can be applied to the imaging section 12031. Applying the technology according to the present disclosure to the imaging section 12031 enables imaged images easier to view to be obtained by shake correction or the like. Therefore, it is possible to reduce fatigue of the driver.

It should be noted that the above-mentioned embodiments show examples for embodying the present technology and matters in the embodiments and invention-specifying matters in the scope of claims respectively correspond to each other. Similarly, invention-specifying matters in the scope of claims and matters in the embodiments of the present technology, which are denoted by the same names, respectively correspond to each other. It should be noted that the present technology is not limited to the embodiments and can be embodied by variously modifying the embodiments without departing from the gist.

It should be noted that the effects described in the present specification are merely exemplary, not limitative, and other effects may be provided.

It should be noted that the present technology may also take the following configurations.

(1) A semiconductor package, including:
a laminated chip that measures a temperature and estimates a degree of warpage of the laminated chip on the basis of the temperature; and
a measurement unit that performs processing of measuring a predetermined physical quantity and generating measurement information and processing of correcting the measurement information on the basis of the degree of warpage.
   (2) The semiconductor package according to (1), in which
the measurement unit corrects the measurement information on the basis of the temperature and the degree of warpage.
   (3) The semiconductor package according to (1) or (2), further including
a substrate having a cavity formed in a predetermined substrate flat surface, in which
a chip flat surface of the laminated chip is connected to a predetermined region of the substrate flat surface, which surrounds the cavity, and
the measurement unit is disposed in a region of the chip flat surface, which is exposed in the cavity.
   (4) The semiconductor package according to (3), in which
in the predetermined region of the substrate flat surface, which surrounds the cavity, a ground pattern and a terminal disposed in vicinity of the ground pattern are disposed.
   (5) The semiconductor package according to (3), in which
in the predetermined region of the substrate flat surface, which surrounds the cavity, a ground pattern including an island-like region and a terminal formed inside the island-like region are disposed.
   (6) The semiconductor package according to any one of (3) to (5), further including
a dummy silicon disposed in the region of the chip flat surface, which is exposed in the cavity.
   (7) The semiconductor package according to any one of (3) to (6), in which
the laminated chip includes a plurality of chips laminated, and
any one of the plurality of chips and the substrate are joined to each other through a wire.
   (8) The semiconductor package according to any one of (3) to (7), in which
the laminated chip and the substrate are connected to each other with a resin.
   (9) The semiconductor package according to any one of (3) to (8), further including
a metal plate bonded to the substrate.
   (10) The semiconductor package according to any one of (3) to (9), in which
the measurement unit includes
   an inertial sensor that has a movable portion exposed in the cavity and generates inertial information as the measurement information, and
   a correction circuit that corrects the inertial information on the basis of the degree of warpage.
      (11) The semiconductor package according to (10), in which
the measurement unit further includes a silicon cap that seals the movable portion.
   (12) The semiconductor package according to any one of (1) to (11), in which
the laminated chip includes a sensor chip that generates image data.
   (13) The semiconductor package according to (12), in which
the sensor chip processes the image data by using the corrected measurement information.
   (14) A module, including:
a laminated chip that measures a temperature and estimates a degree of warpage of the laminated chip on the basis of the temperature; and
a measurement unit that performs processing of measuring a predetermined physical quantity and generating measurement information and processing of correcting the measurement information on the basis of the degree of warpage.

### REFERENCE SIGNS LIST

100 semiconductor package
110 sensor chip
111 vertical driving unit
112 pixel array section
113 column signal processor
114 temperature sensor
115 image processor
120 control chip
121 warpage information converter
125 laminated chip
130, 130-1, 130-2 inertial measurement unit
131, 132 movable portion
133, 134 MEMS
135 correction circuit
136 silicon cap
141, 142 terminal
143 ground pattern
144, 145 pad
146 resin
150 substrate
160 dummy silicon
170 metal plate
191 glass
192 frame
200 sensor module
210 electronic component
12031 imaging unit

What is claimed is:

1. A semiconductor package, comprising:
a laminated chip that measures a temperature and estimates a degree of warpage of the laminated chip on a basis of the temperature; and
a measurement unit that performs processing of measuring a predetermined physical quantity and generating measurement information and processing of correcting the measurement information on a basis of the degree of warpage.

2. The semiconductor package according to claim 1, wherein
the measurement unit corrects the measurement information on a basis of the temperature and the degree of warpage.

3. The semiconductor package according to claim 1, further comprising
a substrate having a cavity formed in a predetermined substrate flat surface, wherein
a chip flat surface of the laminated chip is connected to a predetermined region of the substrate flat surface, which surrounds the cavity, and
the measurement unit is disposed in a region of the chip flat surface, which is exposed in the cavity.

4. The semiconductor package according to claim 3, wherein
in the predetermined region of the substrate flat surface, which surrounds the cavity, a ground pattern and a terminal disposed in vicinity of the ground pattern are disposed.

5. The semiconductor package according to claim 3, wherein
in the predetermined region of the substrate flat surface, which surrounds the cavity, a ground pattern including an island-like region and a terminal formed inside the island-like region are disposed.

6. The semiconductor package according to claim 3, further comprising
a dummy silicon disposed in the region of the chip flat surface, which is exposed in the cavity.

7. The semiconductor package according to claim 3, wherein
the laminated chip includes a plurality of chips laminated, and
any one of the plurality of chips and the substrate are joined to each other through a wire.

8. The semiconductor package according to claim 3, wherein
the laminated chip and the substrate are connected to each other with a resin.

9. The semiconductor package according to claim 3, further comprising
a metal plate bonded to the substrate.

10. The semiconductor package according to claim 3, wherein
the measurement unit includes
an inertial sensor that has a movable portion exposed in the cavity and generates inertial information as the measurement information, and
a correction circuit that corrects the inertial information on a basis of the degree of warpage.

11. The semiconductor package according to claim 10, wherein
the measurement unit further includes a silicon cap that seals the movable portion.

12. The semiconductor package according to claim 1, wherein
the laminated chip includes a sensor chip that generates image data.

13. The semiconductor package according to claim 12, wherein
the sensor chip processes the image data by using the corrected measurement information.

14. A module, comprising:
a laminated chip that measures a temperature and estimates a degree of warpage of the laminated chip on a basis of the temperature; and
a measurement unit that performs processing of measuring a predetermined physical quantity and generating measurement information and processing of correcting the measurement information on a basis of the degree of warpage.
